(19) United States
(12) Patent Application Publication
(10) Pub. No.: US 2005/0190831 A1
(43) Pub. Date: Sep. 1, 2005

(54) Digital filter enabling consecutive readout of filter coefficients from a continuous sequence of storage locations during convolution calculation

(75) Inventor: Toshiyuki Fukushima, Kariya-shi (JP)

Correspondence Address: NIXON & VANDERHYE, PC, 901 NORTH GLEBE ROAD, 11TH FLOOR, ARLINGTON, VA, 22203, US

(73) Assignee: DENSO CORPORATION, Kariya-city (JP)

(21) Appl. No.: 11/065,261

(22) Filed: Feb. 25, 2005

(30) Foreign Application Priority Data
Mar. 1, 2004 (JP) 2004-56641

(51) Int. Cl. H03K 5/159

(52) U.S. Cl. 375/232

(57) ABSTRACT

A digital filter performs a convolution calculation on each of successively updated sets of N stored data values, with the calculation including multiplying each data value by a specific corresponding one of a set of N filter coefficients, wherein the N filter coefficients are respectively held in a first continuous sequence of storage locations and at least (N−1) of the filter coefficients are also respectively held in a second continuous sequence of storage locations, with these sequences constituting a single continuous sequence of storage locations from which the N filter coefficients are consecutively read out during a convolution calculation.

### CROSS-REFERENCE TO RELATED APPLICATIONS

This application is based on and incorporates herein by reference Japanese Patent Application No. 2004-056641 filed on Mar. 1, 2004.

### BACKGROUND OF THE INVENTION

1. Field of Application

The present invention relates to a digital filter that performs filter calculations (specifically, convolution calculations) whereby each of respective data values that are successively acquired at fixed periodic intervals is multiplied by a corresponding filter coefficient, with the resultant products being summed.

A digital filter according to the present invention can for example be used in conjunction with an engine ECU (electronic control unit) for processing of frequencies of vibration of a vehicle engine, to detect any occurrence of engine knock.

2. Description of Prior Art

FIR (Finite Impulse Response) filters are widely used in such a type of filter processing application. A FIR filter can be implemented by storing each of respective data values (where the term “data value” is used herein to refer to a datum expressed as a digital value) successively acquired at fixed periodic intervals, in a storage device such as a RAM (Random Access Memory), with the data values being stored one at a time in respective storage locations of the storage device such that when a most recently acquired data value is stored, it replaces the oldest stored data value. In that way it is ensured that a set of data values, consisting of a fixed number of values, are held in respective storage locations, with these data values extending from the most recently stored value to the oldest stored value.

With such a method of sequentially storing data, when the amount of filter calculation processing that must be executed becomes large, the amount of data used in the calculations also becomes large, and in addition the amount of data that must be moved (in the process of performing the filter calculations) becomes accordingly large. Hence a substantial increase in processing load occurs as a result of processing that must be performed for transferring data.

If a ring buffer (i.e., circular buffer) configuration is used for storing the inputted data values that are used in the filter calculations, then it is only necessary to replace the oldest data value by the newest data value, without changing the storage locations of the remaining data values. However in that case, in order to establish a requisite corresponding between the stored data values and the respective filter coefficients, it is necessary to rearrange the data values in order of their input sequence (i.e., time axis sequence), with the rearranged data being stored in another buffer. Hence it becomes necessary to provide additional data storage capacity for the rearranged data, and in addition the processing load is increased by the need to perform the rearrangement operations.

Furthermore when such a ring buffer arrangement is used, it is possible to use relative addresses for specifying the addresses from which data values are to be read out from the ring buffer, while establishing the requisite correspondence between the data values and the filter coefficients. However in that case, each time a data value is read out, it is necessary to judge whether or not the address from which that data value is read out is the final address of the ring buffer, and if so, to set the address which immediately follows the final address as being the leading address. Hence, the calculation processing load is increased by the need to perform such judgement and setting processing operations.

A digital filter designed to overcome the above problems has been previously proposed by the assignee of the present invention, in Japanese patent laid-open No. 2003-87098, referred to in the following as reference document 1. With the digital filter of reference document 1, 2N storage locations are provided, i.e., capable of storing respective ones of 2N data values (where the number of data values required to perform a filter calculation is N). When the most recent data value (i.e., obtained by D/A conversion) is acquired, that data value is stored concurrently in two storage locations that are disposed N locations apart from one another. The storage location for the most recent data value is incremented by one each time that such a storage operation is performed. When a condition has been reached whereby one of the two storage location of a data value has become the final one of the 2N storage locations, then the pair of storage destinations for the newest input data value are reset to become the leading one of the 2N storage locations, and a storage location that is separated by N locations from the leading storage location, respectively.

The terms “leading storage location” and “final storage location” of a continuous sequence of storage locations, as used herein, can for example correspond to the lowest-numbered and the highest-numbered ones of a continuous sequence of memory addresses, that can be consecutively selected by successively incrementing an index pointer (i.e., address pointer).

With such a method of storing data, whereby each of the N data values used in a filter calculation is stored in two different storage locations, the data are stored in a continuous sequence of storage locations. Hence, as data values are read out, it is only necessary to continuously update the addresses, without the need for judging whether or not a final address has been reached. Thus, the calculation processing load can be reduced, and the speed of filter calculation processing can be increased.

However with such a form of digital filter, it is necessary to store each newest data value concurrently in two different storage locations. Hence, the processing time required to execute a convolution calculation, as a filter processing operation, becomes increased. It would therefore be desirable to provide a digital filter which provides not only a reduction of the processing load that results from performing such a calculation, but also enables a reduction in the time required to execute each calculation.

### SUMMARY OF THE INVENTION

It is an objective of the present invention to overcome the above problems of the prior art by providing an improved digital filter whereby the processing load and the time required to perform filter processing operations can be reduced.

To achieve the above objective, the invention provides a digital filter for operating on each of successive sets of N data values where N is a plural integer, to perform a filter processing operation that includes multiplying each of the N data values by a corresponding one of a set of N filter coefficient, with each of the successive sets being formed by updating to replace an oldest data value of the set by a newly acquired data value, with the digital filter including:
(a) data storage means having N data storage locations, for storing each of the successive sets of N data values, with successive ones of the N storage locations (extending from a leading storage location to a final storage location) being sequentially selected to store successive newly acquired data values, and with the leading storage location being selected after a newly acquired data value has been stored in the final storage location;
   (b) filter coefficient storage means having two sets of filter coefficient storage locations, each being a continuous sequence of storage locations and with the two sets forming a single continuous sequence of storage locations, with one of the two sets of storage locations having the N filter coefficients stored therein and the other set having at least (N−1) of the filter coefficients also stored therein, and
   (c) index means for designating one of the storage locations of the filter coefficient storage means as being the storage location of the filter coefficient that corresponds to the data value stored in the leading storage location of the data storage means.

In executing a convolution calculation, the N filter coefficients are read out in succession from consecutive locations of the filter coefficient storage means, commencing from the storage location that is designated by the index means. As each filter coefficient is read out, it is used to multiply the corresponding one of the data values, read out from the data storage means.

The advantages of this are as follows. Firstly, it is only necessary to provide data storage means for storing the most recently acquired N data values. Secondly, it is not necessary to perform processing to judge the storage locations from which the filter coefficients are successively read out (i.e., to determine when it is necessary to jump to a non-consecutive storage location in the filter coefficient storage means). Instead, it is only necessary to successively select N consecutive storage locations in the filter coefficient storage means, during a filter calculation operation. Thus, the processing is substantially simplified by comparison with the prior art. This is due to the fact that, when a convolution calculation is started, then irrespective of the particular storage location that is designated by the index means as corresponding to the data value stored in the leading storage location of the data storage means, an appropriate set of N successive locations in the filter coefficient storage means can be consecutively selected for readout of respective filter coefficients, without the possibility of reaching the end of the aforementioned single continuous sequence of storage locations.

Moreover, control of the index means can be simple. Specifically, the location in the filter coefficient storage means that is indicated by the index means is shifted by one storage location position, along the same shift direction, each time a new data value is written into the data storage means.

### BRIEF DESCRIPTION OF THE DRAWINGS

FIG. 1 is a block diagram showing the overall configuration of a system for detecting engine knock, incorporating an embodiment of a digital filter according to the present invention;

FIGS. 2A, 2B, 2C are waveform diagrams for use in describing the operation of the embodiment of FIG. 1;

FIG. 3 is a block diagram conceptually illustrating the configuration of a digital filter section shown in FIG. 1;

FIGS. 4A to 4D are diagrams for illustrating movement of data in a data buffer shown in FIG. 3;

FIG. 5 is a diagram for describing the basic principles of a convolution calculation;

FIG. 6 is a diagram showing details of a filter coefficient storage section 64 shown in FIG. 3;

FIG. 7 is a diagram for describing a convolution calculation utilizing the data buffer 62 and filter coefficient storage section 64 shown in FIG. 3;

FIG. 8 is a flow diagram of initialization processing that is executed when power is applied to an ECU 40 in the system of FIG. 1;

FIG. 9 is a flow diagram showing overall processing that is executed by the ECU 40, when an A/D conversion operation on a knock signal has been performed;

FIG. 10 is a flow diagram showing A/D converted value acquisition processing, corresponding to FIG. 9;

FIG. 11 is a flow diagram of filter calculation processing, corresponding to FIG. 9;

FIG. 12 is a flow diagram of processing to calculate an updated value of a convolution start pointer FilPos, corresponding to FIG. 9;

FIG. 13 is a flow diagram of processing executed to store a filter result value, corresponding to FIG. 9; and

FIGS. 14A to 14D and FIGS. 15A to 15D are diagrams for use in describing the operation of the convolution start pointer.

### DESCRIPTION OF PREFERRED EMBODIMENTS

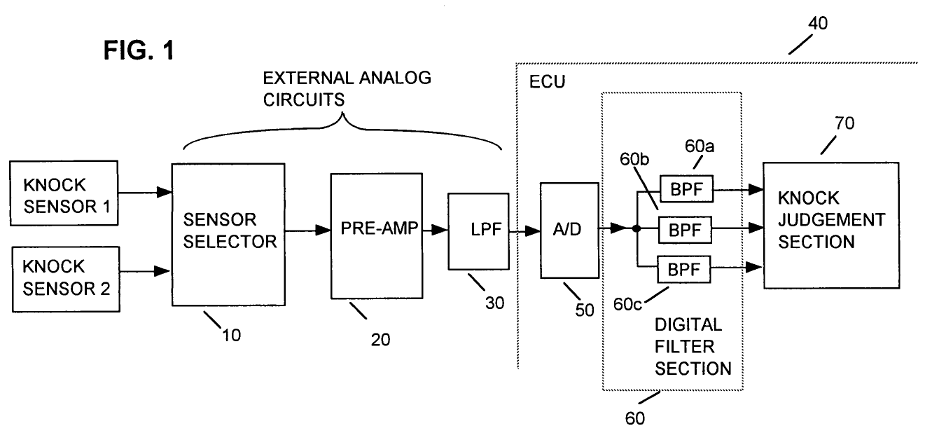

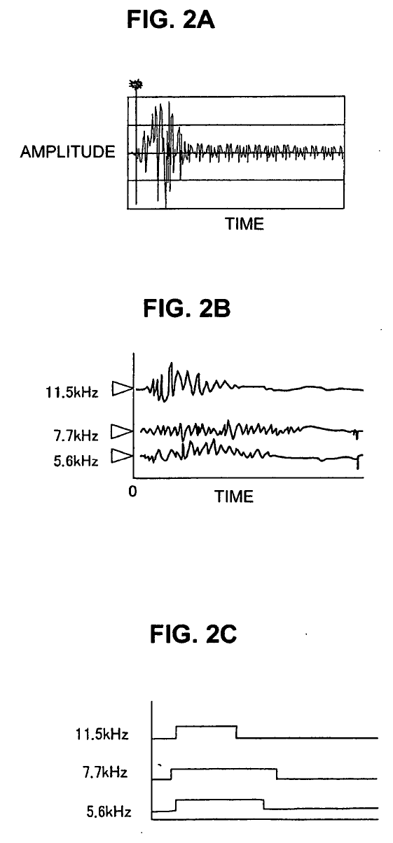

FIG. 1 is a block diagram of an embodiment of a digital filter according to the present invention, which is applicable to processing an output signal from a knock sensor, for detecting an occurrence of engine knock in a vehicle engine. As shown in FIG. 1, the embodiment receives output signals produced from first and second knock sensors (knock sensor 1, knock sensor 2), with these signals expressing the amplitude and frequency of vibration of an engine (not shown in the drawings). FIG. 2A shows an example of an output signal from such a knock sensor. The reason for providing a plurality of knock sensors is that a vehicle engine generally has more than two cylinders, and typically there would be one knock sensor provided for every two cylinders of the engine.

Referring again to FIG. 1, a sensor selector 10 receives the respective output signals from the knock sensors 1, 2 and selects one of these to be outputted to a preamplifier 20. The sensor selector 10 periodically changes over the selected knock sensor output signal, at regular intervals. The preamplifier 20 amplifies the selected knock signal, and the amplified signal is supplied to a LPF (low-pass filter) 30, which extracts high-frequency components of the amplified knock signal, for use in judging whether these high-frequency components constitute a noise component that is indicative of occurrence of engine knock.

The sensor selector 10, preamplifier 20 and LPF 30 are constituted as respective analog circuits, disposed external to an ECU 40 that is described in the following.

The high-frequency components of the amplified knock signal that are extracted by the LPF 30 are inputted to an A/D converter 50 in the ECU 40. The ECU 40 further includes a digital filter section 60 and a knock judgement section 70 as shown. The A/D converter 50 converts the input signal from the LPF 30 from analog to digital signal form, by periodically sampling that input signal and converting the samples to respective (digital) data values. The resultant sequence of data values are inputted to the digital filter section 60, which performs digital BPF (bandpass filter) processing of these to extract signal components that are within specific frequency bands. In this embodiment, it is assumed that these frequency bands are respectively centered on 5.6 kHz, 7.7 kHz and 11.5 kHz, with each having a predetermined bandwidth.

Thus, the digital filter section 60 of this embodiment performs filter processing that is equivalent to applying three BPFs 60a, 60b and 60c, as shown conceptually shown in FIG. 1, for respectively extracting the aforementioned frequency bands.

FIG. 2B illustrates an example of waveforms (shown in analog form) of output signals thereby obtained by the BPFs 60, 60b, 60c respectively.

The knock judgement section 70 judges whether engine knock is occurring, based upon the signal components in the respective frequency bands that have been processed by the digital filter section 60. For example, a decision can be made as to the occurrence of engine knock by judging the degree of pattern matching between the signal components in the respective frequency bands and a set of characteristic patterns that respectively correspond to these frequency bands and that are indicative of occurrence of engine knock. An example of such a set of characteristic patterns is shown in FIG. 2C. With this embodiment, the knock judgement section 70 compares the time axis variations of the respective signal components selected by the filter frequency bands (e.g., the three signal components shown in FIG. 2B) with the corresponding characteristic patterns shown in FIG. 2C. If the degree of pattern matching between the band-selected frequency components and the characteristic patterns is sufficiently high, then the knock judgement section 70 judges that engine knock is occurring.

By performing frequency analysis of the knock signals using digital filtering as described above, the accuracy of judging the occurrence of engine knock can be substantially enhanced, with that accuracy being less affected by noise than would be the case if analog filtering were to be employed.

Although not shown in the drawings, the ECU 40 has a function of appropriately adjusting the ignition timing of the vehicle engine operation (specifically, the ignition timing delay angle), when it is detected that engine knock is occurring.

It can thus be understood that with this embodiment, the ECU 40 that performs engine control is also configured to perform digital signal processing. However if the ECU 40 were to be configured to implement a conventional type of digital filter for performing such frequency analysis processing, then the manufacturing cost of the ECU 40 would become excessive, making it impractical to utilize such an engine ECU. Even if a dedicated ECU were to be employed to perform such frequency analysis processing for knock detection (i.e., separate from the engine ECU), it would be difficult to achieve satisfactory operating by using a conventional type of digital filter configuration, due to large amounts of processing delay that would occur.

The greatest source of processing load that is imposed by frequency analysis processing using a digital filter is that of convolution calculations, described hereinafter. The present invention makes it possible to reduce the amount of processing required to perform such convolution calculations, so that the ECU 40 can perform such processing while also performing engine control functions.

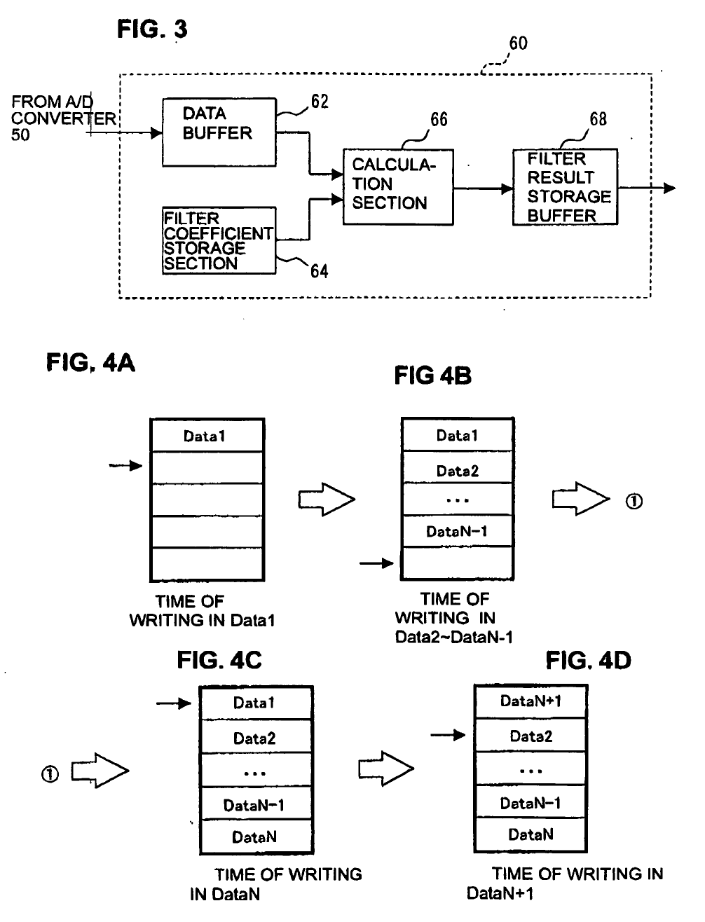

The configuration and operation of the digital filter section 60 of the ECU 40 of this embodiment, whereby the amount of processing required to perform the convolution calculations for digital filter processing can be reduced, will be described in the following. FIG. 3 is a block diagram which illustrates how the digital filter section 60 implements the aforementioned band-pass filter function. The contents of FIG. 3, and the following description, are applicable to each of the BPFs 60a to 60c of FIG. 1. As shown, the digital filter section 60 includes a data buffer 62, a filter coefficient storage section 64, a calculation section 66 and a filter result buffer 68. The data buffer 62 is provided with a set of N storage locations, holding respective ones of N data values that have been sequentially acquired (from the A/D converter 50) and written into successive storage locations, i.e., with these data values extending from a most recently acquired data value to an oldest precedingly acquired data value. FIG. 4A (described in detail hereinafter) illustrates the N storage locations, with the most recently acquired data value designated as Data1. The lowermost storage location shown in FIG. 4A will be referred to as the “final storage location”, and the uppermost storage location in FIG. 4A will be referred to as the “leading storage location”, so that a ring buffer configuration is formed.

Successive changes in the storage location of the data buffer 62 into which a most recently acquired data value is written will be described in the following, referring to FIGS. 4A to 4D. The value of a buffer pointer, referred to as DataPos, designates the storage location into which the next most recently acquired data value is to be written. In the condition illustrated in FIG. 4A, write-in of Data1 (as the most recently acquired data value) into the leading storage location has been completed, so that the buffer pointer DataPos has been incremented by one, and now points to the second storage location.

FIG. 4B illustrates the condition in which the buffer pointer DataPos has been successively incremented until the data values Data1 to DataN−1 have been sequentially written into respective storage locations. When the next most recently acquired data value DataN is now written into the final storage location (i.e., the N-th storage location), then when that operation has been completed, the buffer pointer DataPos is reset to again point to the leading storage location, as shown in FIG. 4C.

As a result, the next most recently acquired data value (DataN+1) is written into the leading storage location, replacing the oldest data value (Data1), as shown in FIG. 4D.

By using the buffer pointer DataPos in that way to designate successive storage locations of the data buffer 62, the destination storage location for the most recently acquired data value is successively returned from the final storage location to the leading storage location. In addition, it is ensured that the data buffer 62 always holds a set of N data values that extend from the most recently acquired data value to an oldest acquired data value.

Each time that write-in of a most recently acquired data value has been completed, the N data values that are currently held in the data buffer 62 are then successively read out while at the same time the filter coefficients respectively corresponding to these data values are successively read out from the filter coefficient storage section 64, and a convolution calculation is performed by the calculation section 66, utilizing the read-out data values and filter coefficients. The result is stored in the filter result buffer 68, to be supplied to the knock judgement section 70.

The above operations are performed respectively separately for each of the plurality of frequency bands that are to be selected, and respectively separate sets of filter coefficients are held in the filter coefficient storage section 64, corresponding to the different frequency bands. To perform a convolution calculation for a specific frequency band (i.e., to implement the function of a specific one of the BPFs 60a, 60b, 60c), the corresponding set of filter coefficients are read out from the filter coefficient storage section 64, and used in conjunction with the N data values that are read out from the data buffer 62 as described above, to obtain a filter result value that is then registered in the filter result buffer 68.

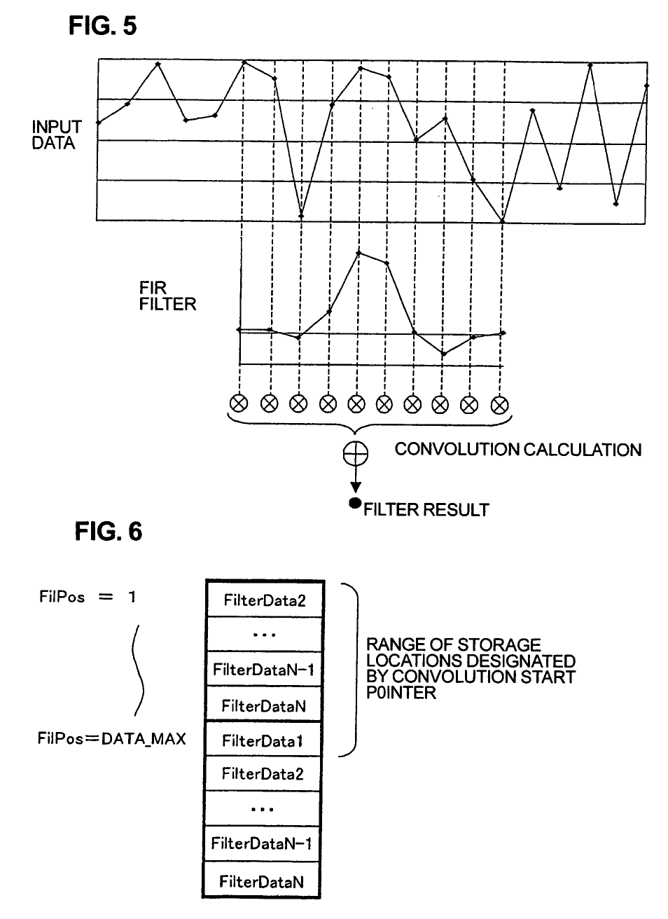

A simple description of the convolution calculation will be given referring to FIG. 5. (The following description, and the succeeding description of the filter coefficient storage section 64, relate to the processing performed to implement the function of one of the plurality of BPFs 60a, 60b, 60c, i.e., using one specific set of N filter coefficients.) As illustrated in FIG. 5, a set of N data values, read out from the data buffer 62 as described above, are respectively multiplied by corresponding ones of a set of N filter coefficients (read out from the filter coefficient storage section 64 as described above), and the resultant products are summed to obtain a filter calculation result value. Thus, each time such a calculation is performed, a large amount of processing is necessary, i.e., both for performing the multiplication and summing operations and also for performing data read-out operations on the N data values and the N filter coefficients. All of these operations must be performed (for each of the plurality of frequency bands) each time a newly acquired data value is written into the data buffer 62, so that the frequency of executing the convolution calculations is very high. Hence, it is important to reduce the amount of processing required to perform such a filter calculation, in order to minimize the processing load that is imposed on the ECU 40.

With this embodiment as shown in FIG. 6, the filter coefficient storage section 64 is provided with a total of (2N−1) filter coefficient storage locations. A set of N filter coefficients will be designated as FilterData1, FilterData2 . . . , FilterDataN. In the filter coefficient storage section 64, a continuous sequence of (N−1) storage locations (referred to in the following as set No. 1) have all of the N filter coefficients other than the initial filter coefficient FilterData1 stored therein, i.e., have the filter coefficients FilterData2, FilterData3 . . . , FilterDataN successively stored therein. In addition, a continuous sequence of N storage locations in the filter coefficient storage section 64 (referred to in the following as set No. 2) have all of the N filter coefficients FilterData1, FilterData2 . . . , FilterDataN successively stored therein, as illustrated in FIG. 6, with set No. 2 extending continuously from the end of set No. 1 as shown. As described in the following, this arrangement enables the amount of processing required to perform filter calculations to be substantially reduced.

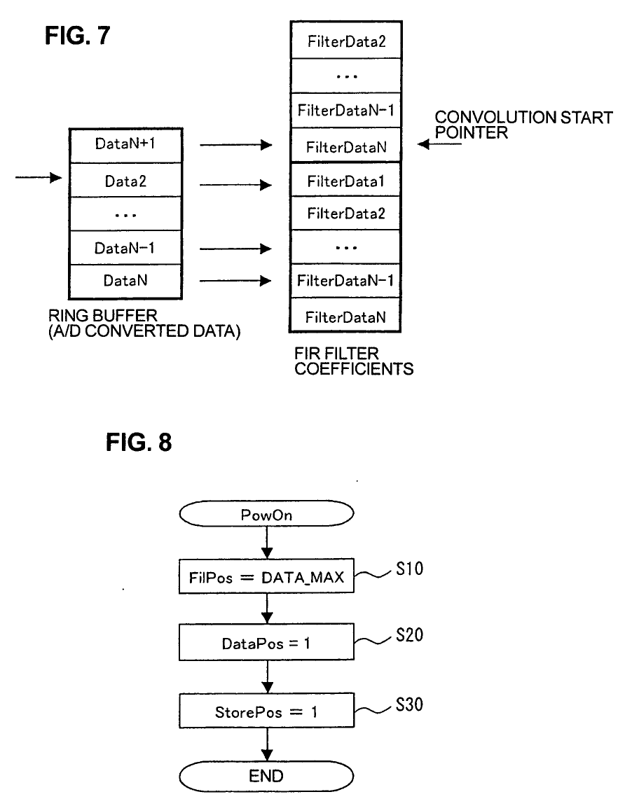

Specifically, by using a convolution start pointer FilPos as shown in FIG. 7, to point to the storage location of the filter coefficient corresponding to the data value that is currently held in the leading storage location (i.e., of the N storage locations shown in FIGS. 4A to 4D), the filter coefficients respectively corresponding to the stored data values can be read out from the filter coefficient storage section 64 in a simple manner.

That is to say, when a filter coefficient is read out, it is not necessary to judge whether the final storage location of the filter coefficient storage section 64 has been reached, and it is only necessary to update the storage location indicated by the convolution start pointer FilPos (i.e., by incrementing the pointer value by 1). In that way, the filter coefficients can be successively read out from the filter coefficient storage section 64 together with successive read-out of the corresponding data values from the data buffer 62.

With the example shown in FIG. 7, the most recently acquired data value supplied from the A/D converter 50 is DataN+1, which is held in the leading storage location of the data buffer 62, while the oldest data value is Data2, which is held in the second storage location of the data buffer 62. The filter coefficient that is to be applied to the most recently acquired data value, in the convolution calculation, is FilterDataN. Hence, with the condition shown in FIG. 7, the convolution start pointer FilPos designates the final storage location in the aforementioned No. 1 set of storage locations in the filter coefficient storage section 64, which contains the filter coefficient FilterDataN as shown. When that has been read out, the convolution start pointer FilPos then designates the location of the filter coefficient FilterData1 (which is to be applied to the oldest acquired data value, in the convolution calculation), and thereafter successively designates the storage locations of the remaining filter coefficients in the appropriate sequence, up to the filter coefficient FilterDataN−1, corresponding to the second-newest acquired data value.

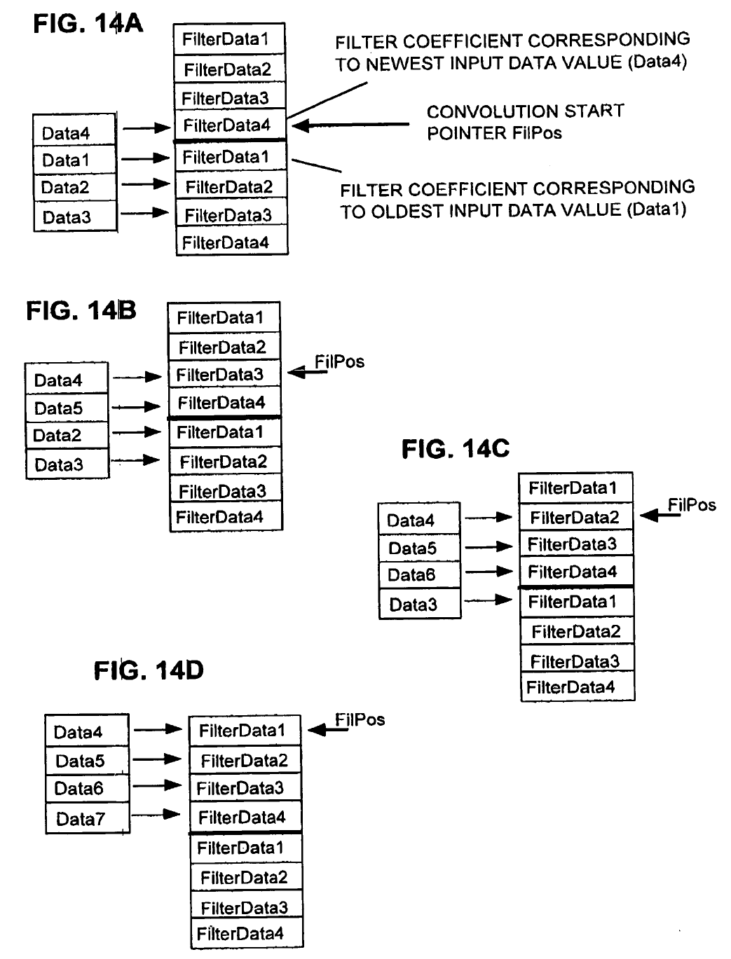

The above description of utilizing the convolution start pointer FilPos has been given on the assumption that the leading filter coefficient of the No. 1 set of coefficients is omitted. However it would be equally possible to instead omit the final filter coefficient of the No. 2 set of filter coefficients. This will be made clear by the following description of the operation example of FIGS. 14A to 14D, in which it is assumed for simplicity of description that N is equal to 4, and each of the aforementioned No. 1 set and No. 2 set of filter coefficients stored in the filter coefficient storage section 64 is assumed to consist of 4 filter coefficients, i.e., 2N filter coefficients are stored in the filter coefficient storage section 64. FIG. 14A shows the condition in which a new data value from the A/D converter 50 has been stored in the data buffer 62, designated as Data4, while the oldest data value is Data1. Hence, the convolution start pointer FilPos designates the storage location of the filter coefficient FilterData4, corresponding to the newest input data value (i.e., which is always utilized to multiply the newest input data value, in each convolution calculation). Thus, when a convolution calculation is now performed, data values Data4, Data1, Data2, Data3 will be read out from successive locations of the data buffer 62, in correspondence with readout of the filter coefficients FilterData4, FilterData1, FilterData2, FilterData3, from successive locations in the filter coefficient storage section 64.

FIG. 14B shows the condition after a succeeding new input value (Data5) has been written into the data buffer 62, replacing the oldest value (Data1). The value of FilPos has now been changed to designate that readout of successive filter coefficients will begin from the location of FilterData3. Hence, when the next convolution calculation is performed, data values Data4, Data5, Data2, Data3 will be read out from successive locations of the data buffer 62, in correspondence with readout of the filter coefficients FilterData3, FilterData4, FilterData1, FilterData2, from successive locations in the filter coefficient storage section 64. It can thereby be ensured that the correspondence between the input data values and the filter coefficients is maintained, e.g., with FilterData4 being read out from the filter coefficient storage section 64 when the newest data value Data5 is read out from the data buffer 62.

Next, as shown in FIG. 14C, with a new data value (Data6) having been stored, the convolution start pointer FilPos value is updated to designate the filter coefficient FilterData2, and the next convolution calculation is performed.

With this example, when the next data value (Data7) has been inputted from the A/D converter 50, the value of FilPos is shifted to designate the leading storage location of set No. 1 of the stored filter coefficients. It will be understood that if this method is applied, then it is not actually necessary to store the final filter coefficient (FilterData4) of set No. 2 of the filter coefficients held in the filter coefficient storage section 64, i.e., the total number of stored filter coefficients can be (2N−1).

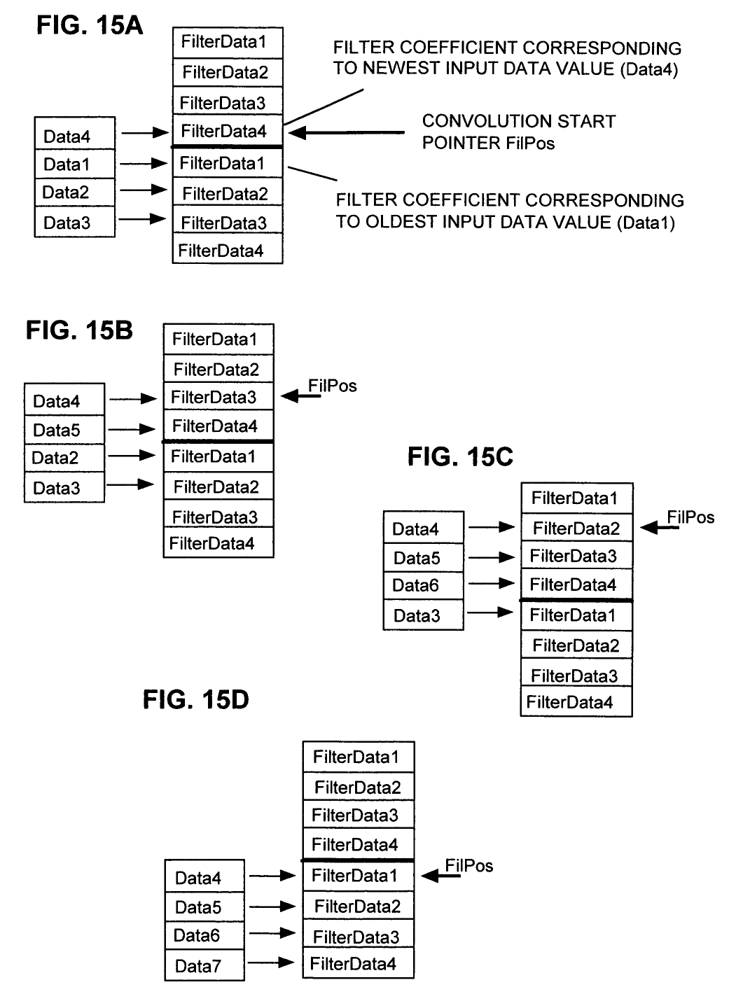

An alternative example is shown in FIG. 15, with FIGS. 15A, 15B, 15C respectively corresponding to FIGS. 14A, 14B, 14C. In this case as shown in FIG. 15D, when the newest data value Data7 is inputted, FilPos is shifted to designate the leading storage location of set No. 2 of the stored filter coefficients. It will be understood that if this method is applied, then it is not necessary to store the initial filter coefficient (FilterData1) of set No. 1 of the filter coefficients held in the filter coefficient storage section 64. This corresponds to the operation described referring to FIGS. 6, 7 above.

As can be understood from the above description, when performing a filter calculation (convolution) operation, the N data values currently held in the data buffer 62 can be respectively read out at the same timings as the corresponding ones of the N filter coefficients are read out from the filter coefficient storage section 64, simply by reading out these data values and filter coefficients from successive ones of a continuous sequence of storage locations (e.g., successively increasing memory address values), with no processing being required to judge whether a jump to a non-consecutive storage location is required, and for calculating the address of such a new storage location. This is achieved by ensuring that, prior to the commencement of a convolution calculation, the convolution start pointer FilPos designates the initial location of a continuous sequence of storage locations in the filter coefficient storage section 64 from which an appropriate set of N filter coefficients will be successively read out for use in the calculation.

Hence, the amount of processing required for read out of data and filter coefficients is greatly reduced by comparison with the prior art.

In addition, the invention has the advantage that it is only necessary to store the N most recently acquired data values, i.e., it is not necessary to store any data values concurrently in two different storage locations, as is necessary with the prior art. Hence by comparison with a prior art type of digital filter, the storage capacity requirements and the amount of processing required to execute a filter calculation are further reduced.

With the example of FIG. 6, in order to read out the N filter coefficients from the continuously extending storage locations of the filter coefficient storage section 64, the storage locations indicated by the convolution start pointer FilPos successively vary within a range that extends from the leading storage location of the aforementioned No. 1 set of storage locations (i.e., when FilPos=1) to the leading storage location of the No. 2 set of storage locations (i.e., when FilPos DATA_MAX).

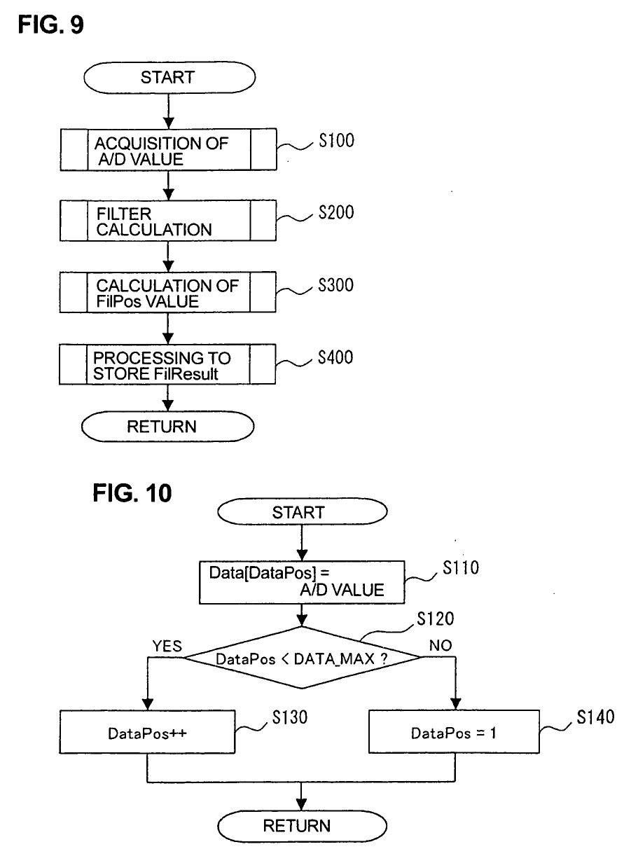

A specific example of this filter processing will be described in the following, that is applicable to the input data value storage and filter coefficient storage configurations of FIGS. 6, 7 above. The processing will be described referring to the flow diagrams of FIGS. 8 to 13. FIG. 8 shows initialization processing that is performed when power is applied to operate the ECU 40. FIG. 9 is a flow diagram of the overall processing that is executed to perform a convolution calculation, performed each time a new data value is acquired, i.e., at each sample timing of an A/D conversion of a knock signal by the A/D converter 50. FIGS. 10 to 13 show details of respective processing operations in FIG. 9.

When power is applied to the ECU 40, then as shown in FIG. 8, firstly in step S10 the index position of the convolution start pointer FilPos is set as DATA_MAX, i.e., designating the leading location of the No. 2 set of filter coefficient storage locations in the filter coefficient storage section 64.

Next in step S20 the buffer pointer DataPos is set to 1, to designate the destination storage location for the first data value that will be inputted from the A/D converter 50. As a result, the leading storage location in the data buffer 62 is designated as that destination storage location. In step S30, a storage position pointer StorePos (which indicates a storage location in the filter result buffer 68 in which the filter calculation result will be registered) is set to 1. In that way, the leading storage location in the filter result buffer 68 is specified as being the destination for registering the first filter coefficient result.

The overall flow of processing for inputting A/D converted data values from the A/D converter 50 will be described referring to FIG. 9. Firstly in step S100, processing to acquire an A/D converted value is performed, i.e., a new data value supplied from the A/D converter 50 is written into a storage location that is specified by the value of the buffer pointer DataPos. Specifically, as shown in FIG. 10, in step S110 an A/D converted value is written into the storage location Data[DataPos] that is specified by the buffer pointer DataPos. Next in step S120 a decision is made as to whether or not the value of the buffer pointer DataPos is less than a value DATA_MAX that corresponds to the total number (N) of data values used in a convolution calculation. If a YES decision is reached, operation proceeds to step S130, in which the buffer pointer DataPos is incremented by one. If there is a NO decision in step S120, then operation proceeds to step S130, in which the buffer pointer DataPos is reset to 1.

The processing executed in steps S120 to S140 serves to alter the value of the buffer pointer DataPos such as to designate the appropriate storage location for the next A/D converted value that will be supplied from the A/D converter 50. As a result of successive executions of that processing, the value of the buffer pointer DataPos successively increases from 1 to DATA_MAX, and is reset to 1 each time that DATA_MAX has been reached.

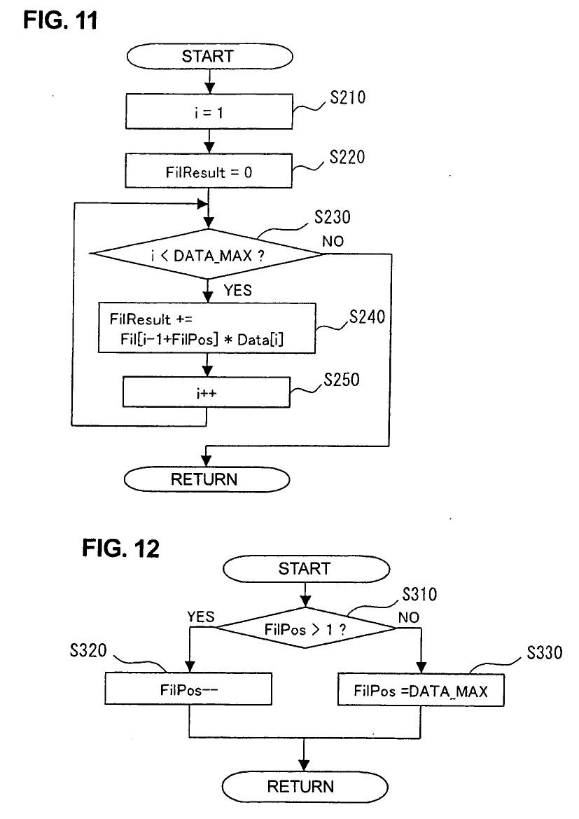

When an A/D converted value acquisition operation has been completed, operation proceeds to step 200 shown in FIG. 9, in which the filter calculation processing is performed. This processing is shown in detail in the flow diagram of FIG. 11, and is executed at each time point when N A/D converted values have become stored in the data buffer 62, after acquiring a new A/D converted value.

Firstly in step S210 of FIG. 11, a variable “i” is set 1, then in step S220 a filter result value FilResult is cleared. In the next step, S130, a decision is made as to whether the value of the variable “i” is smaller than DATA_MAX, which corresponds to the total number (N) of data values used in one convolution calculation. If a NO decision is reached, then since this indicates that a convolution calculation has not yet been completed, operation proceeds to step S240, in which a convolution calculation is executed.

In that step S240, using the variable “i”, the A/D converted values Data[i] are successively read out starting from the leading storage location of the data buffer 62, up to the final storage location. In addition, using the variable “i” and the convolution start pointer FilPos, the filter coefficients Fil[i−1+FilPos] respectively corresponding to the data values Data[i] are read out from the filter coefficient storage section 64, with each data value being multiplied by the corresponding filter coefficient. Each multiplication result thereby obtained is added to the filter result value FilResult.

In step S250, the variable “i” is incremented, and operation returns to step S230. In that way, by successive repetitions of the processing of steps S250 to S250 until the value of the variable “i” reaches DATA_MAX, a convolution calculation using all of the N data values held in the data buffer 62 is completed. When there is a NO decision in step S230, the processing of FIG. 11 is terminated.

On completion of such a filter calculation operation, an updated value for the convolution start pointer FilPos is calculated in step S300 of FIG. 9. Details of this calculation processing are shown in the flow diagram of FIG. 12. Firstly in step S310 of FIG. 12, a decision is made as to whether the value of FilPos is greater than 1. If it is greater than 1, then operation proceeds to step S320, in which FilPos is decremented by 1. If FilPos is not found to be greater than 1, it is set to DATA_MAX in step S330. It can be understood that by successive repetitions of steps 310, 320, starting from a condition in which FilPos is equal to DATA_MAX, a condition will eventually be reached in which a NO decision is reached in step S310, so that FilPos will be reset to the value DATA_MAX.

In that way, after N A/D converted values have been stored in the data buffer 62, then thereafter each time a new A/D converted value is inputted from the A/D converter 50, the value of the convolution start pointer FilPos will be decremented by 1, starting from an initial value of DATA_MAX. It is thereby ensured that each filter coefficient storage location that is indicated by the convolution start pointer FilPos will always correspond to the correct one of the storage locations of the data buffer 62.

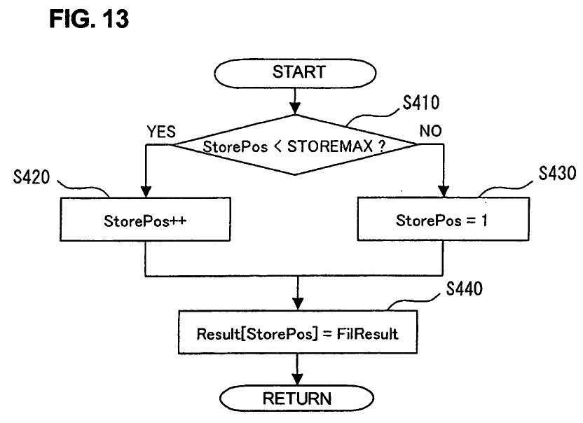

When the calculation processing of the convolution start pointer FilPos has been completed, then in step S400 of FIG. 9, processing is executed to store the filter result FilResult. This will be described referring to the flow diagram of FIG. 13.

Firstly in step S410, a decision is made as to whether the aforementioned storage position pointer StorePos is smaller than a max value STOREMAX, which is a maximum number of convolution calculation results that can be stored. If there is a YES decision in step S410, operation proceeds to step S420, in which the storage position pointer StorePos is incremented by 1. However if StorePos has reached the maximum value STOREMAX, so that there is a NO decision, then operation proceeds to step S430 in which StorePos is set to 1.

Following either of steps S420 or S430, step S440 is then executed, in which the filter result value FilResult is stored in the location Result[StorePos] designated by the storage position pointer StorePos, whose value has been established as described above. In that way a filter processing result, constituting part of the digital filter processing results illustrated in FIG. 2B, is obtained and stored.

It should be noted that the invention is not limited to the preferred embodiment described above, and various modifications could be envisaged. For example with the above embodiment, when (2N−1) filter coefficients are stored as two sets of filter coefficients (as shown in FIG. 6), the leading filter coefficient FilterData1 is omitted from the first of these two sets (set No. 1). However it would be equally possible to instead omit the final filter coefficient FilterDataN from the second of these two sets (set No. 2), as described above referring to FIGS. 14A-14D. However if that is done then it is necessary to initialize the convolution start pointer FilPos to a value of 1.

Furthermore although with the above embodiment, (2N−1) filter coefficients are stored and utilized, it would be equally possible to use a greater number of filter coefficients, e.g., 2N filter coefficients. If that is done, then the aforementioned No. 1 and No. 2 sets of filter coefficients would be stored without omitting the leading filter coefficient or the final filter coefficient from either of these sets. The essential point is that it must be possible to successively read out the N filter coefficients from a continuous sequence of storage locations, while performing a convolution calculation, so that it is unnecessary to perform any processing relating to judging whether a final one of a sequence of filter coefficient storage locations has been reached and to perform any processing that might be required by the result of such judgement. Thus, each convolution calculation can be performed with a minimum of processing load being imposed on the ECU, and in addition can be rapidly performed.

With the above embodiment, the convolution start pointer FilPos is used to determine the initial location from which to read out a filter coefficient from a set of (2N−1) filter coefficient storage locations. However it would be equally possible to determine the initial location from which a filter coefficient is to be read out by referring to the buffer pointer DataPos of the data buffer 62.

It should thus be understood that although the invention has been described above referring to a specific embodiment, various modifications could be envisaged that fall within the scope claimed for the invention.

1. A digital filter which executes a calculation operation on each of successive sets of N data values where N is a plural integer, said calculation operation including multiplying each of said N data values by a corresponding one of a set of N filter coefficients, each of said sets being formed by updating to replace an oldest data value thereof by a new data value, the digital filter comprising:
data storage means having N data storage locations for storing each of said successive sets of N data values, with said updating being applied sequentially to data values extending from that of a leading one to a final one of said N data storage locations and then returning to said leading data storage location;
filter coefficient storage means having first and second sets of N filter coefficient storage locations, each said set having said N filter coefficients stored therein, with said first and second sets constituting a continuously extending sequence of storage locations; and,
index means for designating one of said storage locations of said filter coefficient storage means as being the storage location of a filter coefficient corresponding to said data value that is stored in said leading storage location of said data storage means;
wherein in executing said each calculation operation, N successive ones of said filter coefficients are read out from consecutive storage locations of said filter coefficient storage means, commencing from said storage location that is designated by said index means.

2. A digital filter as claim in claim 1, wherein said storage location that is designated by said index means is shifted by one storage location position each time that a newly acquired data value is stored in said data storage means.

3. A digital filter which executes a calculation operation on each of successive sets of N data values where N is a plural integer, said calculation operation including multiplying each of said N data values by a corresponding one of a set of N filter coefficients, each of said sets of N data values being formed by updating to replace an oldest data value thereof by a new data value, the digital filter comprising:
data storage means having N data storage locations for storing each of said successive sets of N data values, with said updating being applied sequentially to data values extending from that of a leading one to a final one of said N data storage locations and then returning to said leading data storage location;
filter coefficient storage means having a set of N filter coefficient storage locations with said N filter coefficients respectively stored therein and a set of (N−1) filter coefficient storage locations having (N−1) of said N filter coefficients respectively stored therein, each said set having said N filter coefficients stored therein, with said sets of filter coefficient storage locations constituting a continuously extending sequence of storage locations; and,
index means for designating one of said storage locations of said filter coefficient storage means as being the storage location of a filter coefficient corresponding to said data value that is stored in said leading storage location of said data storage means;
wherein in executing said each calculation operation, N successive ones of said filter coefficients are read out from consecutive storage locations of said filter coefficient storage means, commencing from said storage location that is designated by said index means.

4. A digital filter as claimed in claim 3, wherein said storage location that is designated by said index means is shifted by one storage location position each time that a newly acquired data value is stored in said data storage means.

5. A digital filter as claimed in claim 3, wherein said set of N filter coefficient storage locations constitutes a leading part of said continuous sequence of storage locations in said filter coefficient storage means and said set of (N−1) filter coefficient storage locations constitutes a final part of said continuous sequence.

6. A digital filter as claimed in claim 3, wherein said set of (N−1) filter coefficient storage locations constitutes a leading part of said continuous sequence of storage locations in said filter coefficient storage means and said set of N filter coefficient storage locations constitutes a final part of said continuous sequence.
